(19) United States
(12) Patent Application Publication
(10) Pub. No.: US 2026/0089925 A1
(43) Pub. Date: Mar. 26, 2026

(54) SEMICONDUCTOR MEMORY DEVICE AND METHOD OF FABRICATING THE SAME

(71) Applicant: SAMSUNG ELECTRONICS CO., LTD., Suwon-si (KR)

(72) Inventors: Jinnam YEEM, Suwon-si (KR); Jongin KANG, Suwon-si (KR); Hoin LEE, Suwon-si (KR)

(73) Assignee: SAMSUNG ELECTRONICS CO., LTD., Suwon-si (KR)

(21) Appl. No.: 19/095,931

(22) Filed: Mar. 31, 2025

(30) Foreign Application Priority Data
Sep. 26, 2024 (KR) 10-2024-0131042

(51) Int. Cl. H10B 12/00

(52) U.S. Cl. CPC H10B 12/34; H10B 12/09; H10B 12/50

(57) ABSTRACT

A semiconductor memory device includes a substrate including first and second active regions, first and second device isolation structures disposed in the substrate, the first device isolation structure delimiting the first active region, the second active region being between the first device isolation structure and the second device isolation structure, a word line in the substrate, crossing the first and second active regions, and overlapping the second device isolation structure, and a word line connection contact plug spaced apart from the second active region and connected to an end portion of the word line. The word line includes first, second and third conductive patterns. The second conductive pattern is spaced apart from the word line connection contact plug.

### CROSS-REFERENCE TO RELATED APPLICATION

This U.S. non-provisional patent application claims priority under 35 U.S.C. § 119 to Korean Patent Application No. 10-2024-0131042, filed on Sep. 26, 2024, in the Korean Intellectual Property Office, the entire contents of which being hereby incorporated by reference.

### BACKGROUND

The present disclosure relates to a semiconductor memory device and a method of fabricating the same.

Due to their small-sized, multifunctional, and/or low-cost characteristics, semiconductor memory devices are being esteemed as important elements in the electronics industry. With the advancement of the electronic industry, there is an increasing demand for a highly-integrated semiconductor memory device. To increase the integration density of the semiconductor memory device, it is necessary to reduce linewidths of patterns constituting the semiconductor memory device. However, novel and expensive exposure technologies are needed to reduce the linewidths of the patterns, and thus, it becomes difficult to increase the integration density of the semiconductor memory device. Thus, a variety of new technologies are being recently studied to overcome the difficulty in increasing an integration density of a semiconductor memory device.

### SUMMARY

It is an aspect to provide a semiconductor memory device with improved reliability.

It is another aspect to provide a method of fabricating a semiconductor memory device with improved reliability.

According to an aspect of one or more embodiments, there is provided a semiconductor memory device comprising a substrate including a first active region and a second active region; a first device isolation structure and a second device isolation structure disposed in the substrate, the first device isolation structure delimiting the first active region, the second active region being between the first device isolation structure and the second device isolation structure; a word line in the substrate, crossing the first active region and the second active region, and overlapping the second device isolation structure; and a word line connection contact plug spaced apart from the second active region and connected to an end portion of the word line. The word line comprises a first conductive pattern; a second conductive pattern on the first conductive pattern and covering the first active region and the second active region; and a third conductive pattern on the second conductive pattern and covering the first active region. The second conductive pattern is spaced apart from the word line connection contact plug.

According to another aspect of one or more embodiments, there is provided a semiconductor memory device comprising a substrate including a peripheral region, a dummy region, and a cell region sequentially arranged in a first direction; a first device isolation structure disposed in the cell region to delimit first active regions; a second device isolation structure disposed in the dummy region and the peripheral region to delimit second active regions; word lines disposed in the dummy region and the cell region to cross the first active regions and the second active regions in the first direction; and bit lines disposed on the cell region, the bit lines being connected to the first active regions and extending in a second direction orthogonal to the first direction. Each of the word lines comprises a first conductive pattern comprising a first portion on the second device isolation structure and the second active regions, and a second portion on the first active regions; a second conductive pattern on the second portion of the first conductive pattern; and a third conductive pattern interposed between the first conductive pattern and the second conductive pattern. The third conductive pattern extends to cover an end portion of the first portion of the first conductive pattern, and a side surface of the third conductive pattern that is extended is coplanar with an edge of the second device isolation structure.

According to yet another aspect of one or more embodiments, there is provided a semiconductor memory device comprising a substrate including a peripheral region, a dummy region, and a cell region sequentially arranged in a first direction; a first active region and a second active region disposed in the cell region and the dummy region, respectively; and a word line in the substrate, the word line crossing the first active region and the second active region. The word line comprises a first conductive pattern disposed in the cell region and the dummy region; and a second conductive pattern and a third conductive pattern sequentially stacked on the first conductive pattern, in the cell region. A first side surface of the second conductive pattern is coplanar with a second side surface of the third conductive pattern, and the first side surface and the second side surface are adjacent to the dummy region.

According to still yet another aspect of one or more embodiments, there is provided a method of fabricating a semiconductor memory device, the method comprising forming a device isolation structure in a substrate including a cell region and a dummy region to delimit a first active region in the cell region and to delimit a second active region in the dummy region; forming a cover insulating layer on the substrate to delimit a shape of a word line; etching the first active region and the second active region and a portion of the device isolation structure using the cover insulating layer to form a groove in the substrate; forming a gate dielectric layer in the groove; sequentially forming a first conductive pattern and a second conductive pattern in the groove; forming a preliminary conductive layer to cover the second conductive pattern and the cover insulating layer; etching the preliminary conductive layer to form a third conductive pattern that covers the second conductive pattern on the first active region; and etching the first conductive pattern and the second conductive pattern on the dummy region using a mask pattern. The first conductive pattern, the second conductive pattern, and the third conductive pattern constitute the word line.

### BRIEF DESCRIPTION OF THE DRAWINGS

FIG. 1A is a plan view illustrating a semiconductor memory device according to an embodiment.

FIG. 1B is an enlarged plan view illustrating a portion ‘E1’ of FIG. 1A.

FIGS. 1C and 1D are sectional views taken along a line A-A′ of FIG. 1B.

FIG. 1E is a sectional view taken along a line B-B′ of FIG. 1B.

FIG. 1F is a sectional view taken along a line C-C′ of FIG. 1B.

FIG. 1G is a sectional view taken along a line D-D′ of FIG. 1B.

FIGS. 2A and 2B are enlarged sectional views illustrating some embodiments, specifically, corresponding to a portion ‘E2’ of FIGS. 1C and 1D.

FIGS. 3A to 3H are enlarged views sequentially illustrating a process of fabricating a semiconductor memory device having the section of FIG. 1C.

FIGS. 4A to 4D are enlarged sectional views illustrating some embodiments, specifically, corresponding to the portion ‘E2’ of FIGS. 1C and 1D.

### DETAILED DESCRIPTION

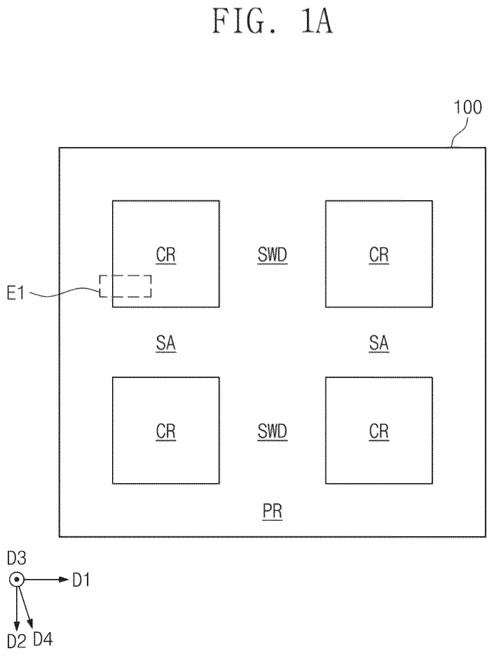

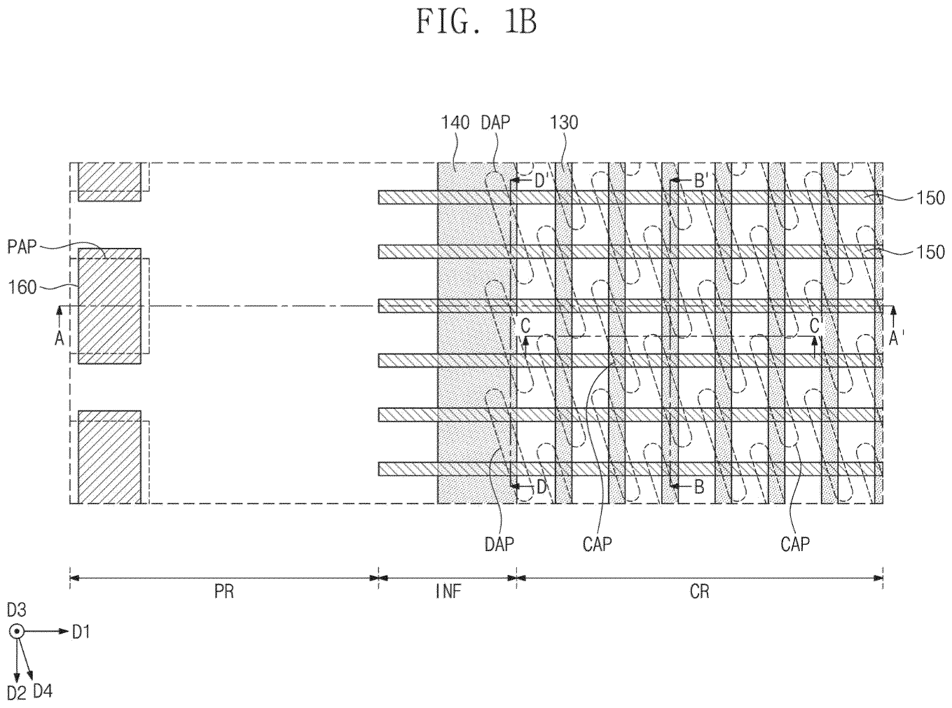

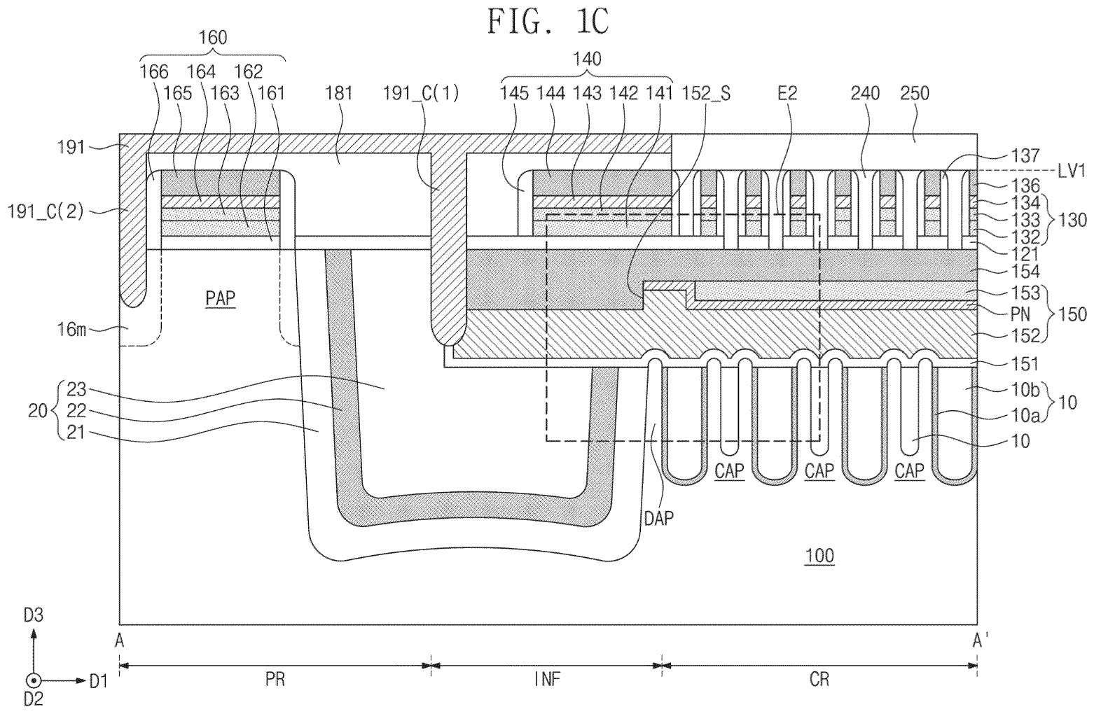

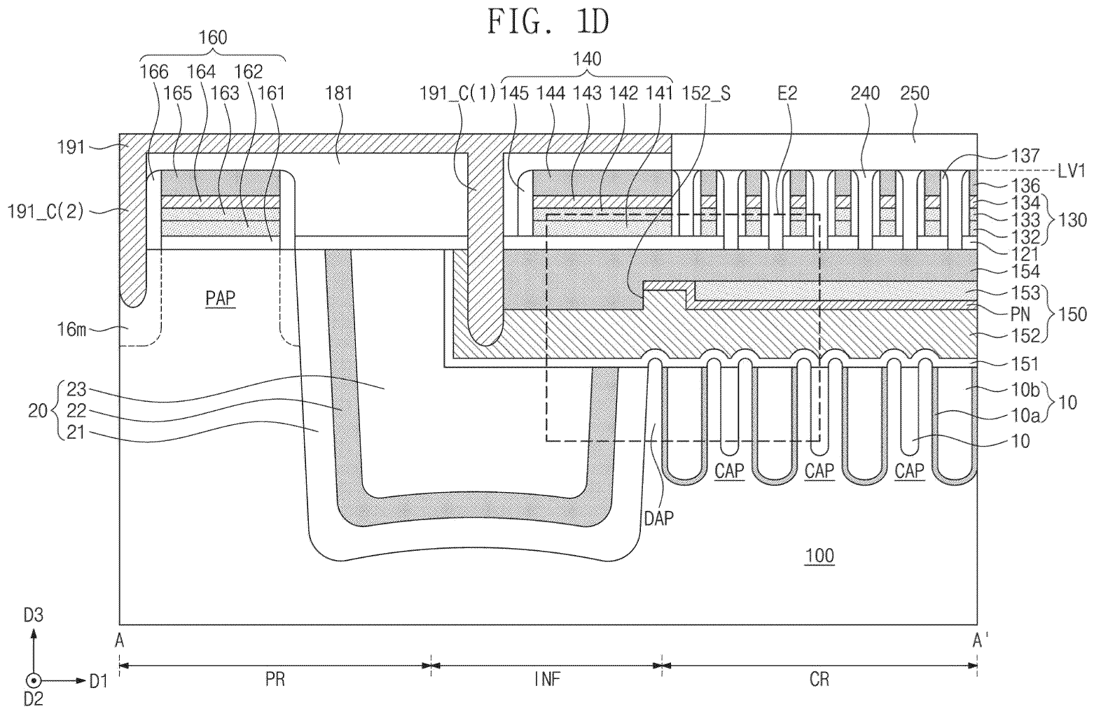

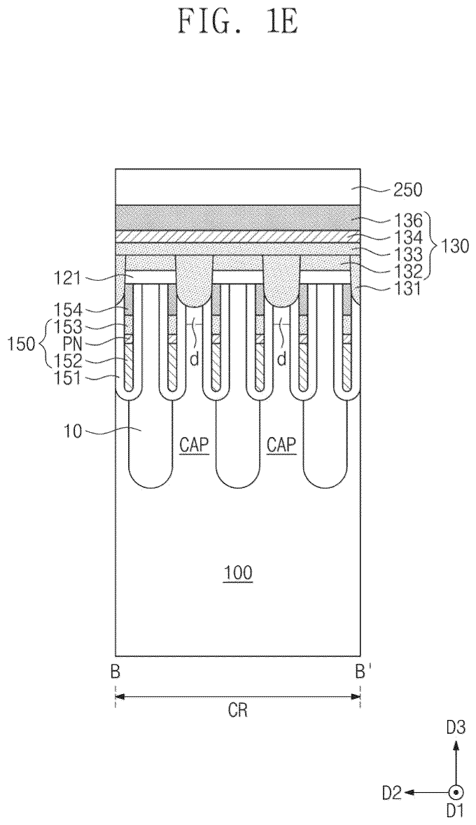

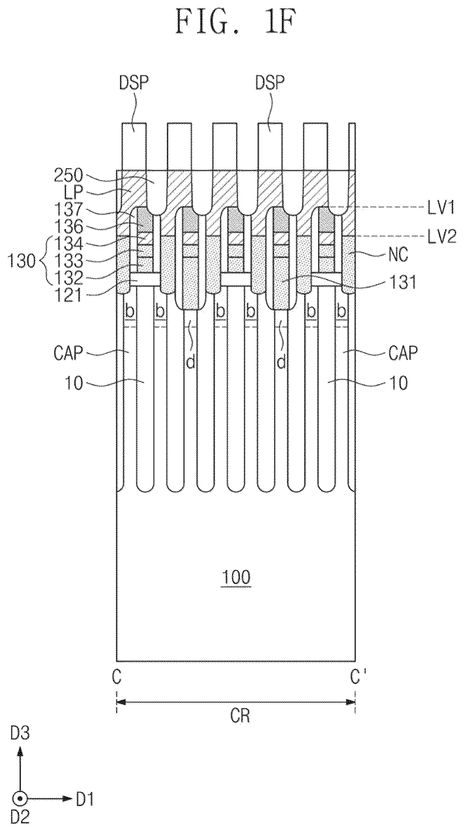

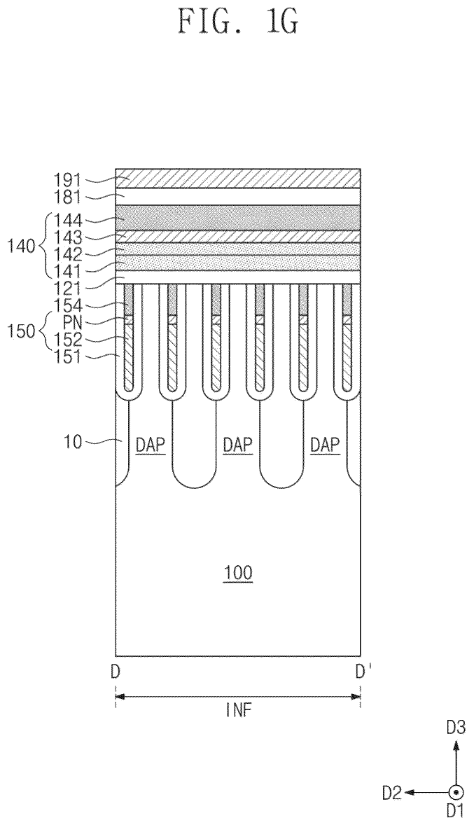

Various embodiments will now be described more fully with reference to the accompanying drawings, in which example embodiments are shown. It will be understood that, although the terms “first”, “second”, etc. may be used herein to describe various elements, components, regions, layers and/or sections, these elements, components, regions, layers and/or sections should not be limited by these terms. As used in this specification, a phrase using the form “at least one of A, B, or C” includes within its scope “only A”, “only B”, “only C”, “A and B”, “A and C”, “B and C” and “A, B, and C. ” FIG. 1A is a plan view illustrating a semiconductor memory device according to an embodiment.

Referring to FIG. 1A, a semiconductor memory device may include a substrate 100. The substrate 100 may be a semiconductor substrate. For example, in some embodiments, the substrate 100 may be formed of or include at least one of silicon, germanium, silicon germanium, gallium phosphide (GaP) or gallium arsenide (GaAs). In some embodiments, the substrate 100 may be a silicon-on-insulator (SOI) substrate or a germanium-on-insulator (GOI) substrate.

The substrate 100 may include a plurality of cell regions CR, which are two-dimensionally arranged in a first direction D1 and a second direction D2 that are orthogonal to each other. The number and arrangement of the cell regions CR are not limited to those of the example illustrated in FIG. 1A and may be variously changed. A peripheral region PR may be disposed between the cell regions CR. The peripheral region PR may be provided to enclose each of the cell regions CR. A plurality of memory cells may be disposed on the cell region CR. Each of the memory cells may be disposed between and connected to a word line and a bit line crossing each other. A core circuit portion or a peripheral circuit portion may be disposed on the peripheral region PR. The peripheral circuit portion may include a row decoder, a column decoder, and/or a control logic circuit.

The core circuit portion of the peripheral region PR may include sense amplifier circuits SA and sub-word line driver circuits SWD. The peripheral region PR may further include power driver circuits and ground driver circuits, which are used to drive the sense amplifier, but embodiments are not limited to this example.

FIG. 1B is an enlarged plan view illustrating a portion ‘E1’ of FIG. 1A. FIGS. 1C and 1D are sectional views taken along a line A-A′ of FIG. 1B. FIG. 1E is a sectional view taken along a line B-B′ of FIG. 1B. FIG. 1F is a sectional view taken along a line C-C′ of FIG. 1B. FIG. 1G is a sectional view taken along a line D-D′ of FIG. 1B.

Referring to FIGS. 1B, 1C, 1D, 1E, 1F, and 1G, the substrate 100 may include the peripheral region PR, a dummy region INF, and the cell region CR, which are sequentially arranged in the first direction D1. The dummy region INF may be placed between the peripheral region PR and the cell region CR. The dummy region may be referred to as a boundary region. Memory cells, which are not dummy cells and configured to actually have the memory function, may be disposed on the cell region CR. Dummy memory cells, which do not have the memory function, may be disposed on the dummy region INF. In an embodiment, the dummy region INF may be provided to prevent a process failure, which may be caused by a loading effect during the fabrication process.

First device isolation structures 10 and second device isolation structures 20 may be disposed in the substrate 100 to delimit first active regions CAP and second active regions DAP, respectively. The first device isolation structures 10 may be disposed on the cell region CR. The second device isolation structures 20 may extend from the dummy region INF to the peripheral region PR. In an embodiment, the first and second device isolation structures 10 and 20 may be connected to each other to form a single object without any boundary.

Upper portions of the cell and dummy regions CR and INF of the substrate 100, which are protruded in a third direction D3, may be defined as the first and second active regions CAP and DAP. The first and second active regions CAP and DAP may be spaced apart from each other. Each of the first and second active regions CAP and DAP may be a bar-shaped structure that is elongated in a fourth direction D4 oblique to the first and second directions D1 and D2. For example, the second active region DAP may be a dummy active region. The second active region DAP may be disposed between the first and second device isolation structures 10 and 20.

Each of the first and second device isolation structures 10 and 20 may be formed of or include at least one of silicon oxide, silicon nitride, or silicon oxynitride and may have a single-layered structure or a multi-layered structure. A portion of each of the first device isolation structures 10 may include a first sub-device isolation insulating layer 10a and a second sub-device isolation insulating layer 10b on the first sub-device isolation insulating layer 10a. The first and second sub-device isolation insulating layers 10a and 10b may include different materials from each other. For example, the first sub-device isolation insulating layer 10a may be formed of or include silicon oxide, and the second sub-device isolation insulating layer 10b may be formed of or include silicon nitride. The second device isolation structure 20 may include a third sub-device isolation insulating layer 21, a fourth sub-device isolation insulating layer 22 on the third sub-device isolation insulating layer 21, and a fifth sub-device isolation insulating layer 23 on the fourth sub-device isolation insulating layer 22. The third to fifth sub-device isolation insulating layers 21, 22, and 23 may include different materials from each other. For example, the third sub-device isolation insulating layer 21 may be formed of or include silicon oxide, the fourth sub-device isolation insulating layer 22 may be formed of or include silicon nitride, and the fifth sub-device isolation insulating layer 23 may be formed of or include silicon oxide.

Word lines 150 may be disposed on the dummy region INF and the cell region CR to cross the first active region CAP and the second active region DAP in the first direction D1. The word line 150 may be provided in a groove, which is formed in the substrate 100 by the first and second device isolation structures 10 and 20 and the first and second active regions CAP and DAP, and may have a buried gate structure. The word lines 150 may be overlapped with the second device isolation structure 20. The word lines 150 may be spaced apart from each other in the second direction D2.

A gate dielectric layer 151 may be disposed between each of the word lines 150 and an inner surface of each groove. For example, the gate dielectric layer 151 may be formed of or include at least one of thermal oxide, silicon nitride, silicon oxynitride, or high-k dielectric materials. The bottom surface of the word line 150 may be uneven.

Referring to FIGS. 1C and 1E, a pair of word lines 150 may be provided on one of the first active regions CAP. For example, two word lines 150 may be provided on one of the first active regions CAP (best seen in FIG. 1E). The paired word lines 150 may be provided to penetrate the first active region CAP in the first direction D1. A first impurity region d may be disposed in each first active region CAP between the paired word lines 150, and a pair of second impurity regions b may be respectively disposed in opposite edge regions of each first active region CAP (see FIG. 1F). The first and second impurity regions d and b may be doped with, for example, n-type impurities. Each of the word lines 150 and the first and second impurity regions d and b adjacent thereto may constitute a cell transistor. Since the word lines 150 are disposed in the grooves, the channel region below the word lines 150 may have an increased channel length, within a given area. Thus, it may be possible to suppress the short channel effect or the like.

The word line 150 may include a first conductive pattern 152, a second conductive pattern PN on the first conductive pattern 152, and a third conductive pattern 153 on the second conductive pattern PN.

The first conductive pattern 152 may cover the gate dielectric layer 151. The second conductive pattern PN may cover the first and second active regions CAP and DAP, on the first conductive pattern 152. The third conductive pattern 153 may cover the first active region CAP, on the second conductive pattern PN.

The first to third conductive patterns 152, PN, and 153 may include conductive materials. The first to third conductive patterns 152, PN, and 153 may include different materials from each other. For example, the first conductive pattern 152 may be formed of or include titanium nitride or tungsten (W). The second conductive pattern PN may be formed of or include molybdenum (Mo). The third conductive pattern 153 may be formed of or include poly silicon. Since the second conductive pattern PN includes molybdenum (Mo) having low resistivity, the resistance of the word line 150 may be reduced. Thus, an operation speed of the semiconductor memory device may be increased.

A word line capping pattern 154 may be disposed in the substrate 100 and on the word line 150. The word line capping pattern 154 may be a line-shaped pattern, which extends in an extension direction of the word line 150 to cover the entire top surface of the word line 150. As shown in FIGS. 1C and 1D, a bottom surface of the word line capping pattern 154 may have a stepwise shape between the cell region CR and the dummy region INF. The word line capping pattern 154 may fill the groove, which is provided on the word line 150. The word line capping pattern 154 may be formed of or include an insulating material (e.g., silicon nitride layer).

An interlayer insulating pattern 121 may be disposed on the substrate 100. The interlayer insulating pattern 121 may be formed of or include at least one of silicon oxide, silicon nitride, or silicon oxynitride layer, and may have a single-layered structure or a multi-layered structure. The interlayer insulating patterns 121 may be island-shaped patterns, which are separated from each other when viewed in a plan view.

Bit lines 130 may be disposed on the interlayer insulating pattern 121. The bit lines 130 may be disposed to cross the word line capping patterns 154 and the word lines 150. As shown in FIG. 1B, the bit lines 130 may be parallel to the second direction D2. The bit lines 130 may include a bit line polysilicon pattern 132, a bit line ohmic pattern 133, and a bit line metal pattern 134, which are sequentially stacked. A bit line capping pattern 136 may be disposed on each of the bit lines 130.

The bit line polysilicon pattern 132 may include doped polysilicon. The bit line ohmic pattern 133 may be formed of or include at least one of titanium, titanium nitride, tantalum, tantalum nitride, tungsten nitride, cobalt silicide, or titanium silicide, and may have a single-layered structure or a multi-layered structure. The bit line metal pattern 134 may include a metallic material (e.g., tungsten, titanium, and/or tantalum). The bit line capping pattern 136 may include an insulating material (e.g., silicon nitride layer).

Bit line contacts 131 may be disposed to cross the bit lines 130 and may be arranged in the second direction D2. The bit line contact 131 may be in contact with the first impurity region d of the first active region CAP. When viewed in the section B-B′ of FIG. 1E, a side surface of the bit line contact 131 may be in contact with a side surface of the interlayer insulating pattern 121. The bit line contacts 131 may include a conductive material. The bit line contacts 131 may be formed of or include, for example, doped polysilicon.

A bit line spacer 137 may cover side surfaces of the bit line capping pattern 136, the bit line polysilicon pattern 132, the bit line ohmic pattern 133, the bit line metal pattern 134, and the bit line contacts 131. The bit line spacer 137 may include an insulating material. In an embodiment, the bit line spacer 137 may include a plurality of insulating layers.

Storage node contacts NC may be disposed between adjacent ones of the bit lines 130. The storage node contacts NC may be spaced apart from each other. The storage node contact NC may be in contact with the second impurity region b of the first active region CAP. The storage node contacts NC may be formed of or include doped polysilicon or undoped polysilicon.

An insulating fence 240 may be disposed between the bit lines 130 and between the storage node contacts NC. The insulating fence 240 may include an insulating layer (e.g., a silicon nitride layer, a silicon oxide layer, and/or a silicon oxynitride layer). The storage node contacts NC and the insulating fences 240 may be alternatingly arranged along the bit line 130 and at a side of each bit line 130. Referring to FIGS. 1C, 1D, and 1F, in an embodiment, a first level LV1 of a top portion of the insulating fence 240 in the third direction D3 may be higher than a second level LV2 of a top portion of the storage node contact NC.

A landing pad LP may be disposed on the storage node contact NC. A portion of the bit line 130 may be vertically overlapped with the landing pad LP. The landing pad LP may include a conductive material. For example, the landing pad LP may be formed of or include a metallic material (e.g., tungsten). In an embodiment, a metal silicide layer may be provided between the storage node contact NC and the landing pad LP. In an embodiment, a diffusion barrier layer may be provided between the storage node contact NC and the landing pad LP. The diffusion barrier layer may be formed of or include at least one of titanium, titanium nitride, tantalum, tantalum nitride, or tungsten nitride, and may have a single-or multi-layered structure.

A landing pad isolation pattern 250 may be disposed between the landing pads LP to separate the landing pads LP from each other. A portion of the landing pad isolation pattern 250 may be provided to penetrate a portion of the bit line capping pattern 136. A portion of the landing pad isolation pattern 250 may be provided to penetrate a portion of the bit line spacer 137 adjacent to the bit line contact 131. The landing pad isolation pattern 250 may have a single-layered structure or a multi-layered structure including at least one of a silicon nitride layer, a silicon oxide layer, a silicon oxynitride layer, or a porous layer.

A data storage pattern DSP may be disposed on the landing pad LP. The data storage pattern DSP may be electrically connected to the landing pad LP. The data storage pattern DSP may be a capacitor including a bottom electrode, a dielectric layer, and a top electrode. In this case, the semiconductor memory device may be a dynamic random-access memory (DRAM) device. In an embodiment, the data storage patterns DSP may include a magnetic tunnel junction pattern. In this case, the semiconductor memory device may be a magnetic random access memory (MRAM) device. In an embodiment, the data storage patterns DSP may include a phase-change material or a variable resistance material. In this case, the semiconductor memory device may be a phase-change random access memory (PRAM) device or a resistive RAM (ReRAM) device. In an embodiment, each of the data storage patterns DSP may include various structures and/or materials which can be used to store data.

In the dummy region INF, a dummy gate structure 140 may be disposed on the interlayer insulating pattern 121. The dummy gate structure 140 may extend in the second direction D2 and may overlap the second active region DAP in the third direction D3. The dummy gate structure 140 may include a first dummy conductive pattern 141, a second dummy conductive pattern 142 on the first dummy conductive pattern 141, a third dummy conductive pattern 143 on the second dummy conductive pattern 142, a dummy capping pattern 144 on the third dummy conductive pattern 143, and a dummy gate spacer 145.

The first to third dummy conductive patterns 141, 142, and 143 may include a conductive material. For example, the first and second dummy conductive patterns 141 and 142 may be formed of or include poly silicon, and the third dummy conductive pattern 143 may be formed of or include a metallic material. The dummy capping pattern 144 may include an insulating material. The dummy gate spacer 145 may cover a side surface of the dummy capping pattern 144 and side surfaces of the first to third dummy conductive patterns 141, 142, and 143. The dummy gate spacer 145 may include an insulating material.

The memory cell structure of FIG. 1C may be disposed on the cell region CR shown in FIG. 1B. However, the dummy gate structure 140, a storage node contact (not shown), and a data storage pattern (not shown) may also be disposed on the dummy region INF in the same shape as shown in FIG. 1C. The dummy gate structure 140, the storage node contact (not shown), and the data storage pattern (not shown), which are disposed on the dummy region INF, may not be operated as an actual memory cell and may be used as dummy patterns preventing the loading effect.

Peripheral active regions PAP may be disposed in an upper portion of the peripheral region PR of the substrate 100. Peripheral gate structures 160 may be disposed on the peripheral region PR of the substrate 100 to face the peripheral active regions PAP. For example, the peripheral gate structure 160 may be used as a gate of a transistor constituting a sub-word line driver. Peripheral impurity regions 16m may be placed in the peripheral active region PAP and next to the peripheral gate structure 160.

The peripheral gate structure 160 may include a peripheral insulating layer 161, a first peripheral conductive pattern 162 on the peripheral insulating layer 161, a second peripheral conductive pattern 163 on the first peripheral conductive pattern 162, a third peripheral conductive pattern 164 on the second peripheral conductive pattern 163, a peripheral capping pattern 165 on the third peripheral conductive pattern 164, and a peripheral gate spacer 166. The first to third peripheral conductive patterns 162, 163, and 164 may include a conductive material. For example, the first and second peripheral conductive patterns 162 and 163 may include poly silicon, and the third peripheral conductive pattern 164 may include a metallic material. The peripheral insulating layer 161, the peripheral capping pattern 165, and the peripheral gate spacer 166 may include an insulating material.

A filling insulating layer 181 may be disposed to cover the dummy gate structure 140 and the peripheral gate structure 160. The filling insulating layer 181 may include an insulating material. For example, the filling insulating layer 181 may include a plurality of insulating layers.

A conductive structure 191 may be disposed on the filling insulating layer 181. The conductive structure 191 may include a conductive material. For example, the conductive structure 191 may include a metallic material (e.g., tungsten). The conductive structure 191 may include a word line connection contact plug 191_C(1), which is connected to the word line 150, and a peripheral connection contact plug 191_C(2), which is connected to the peripheral impurity region 16m of the peripheral active region PAP. The word line connection contact plug 191_C(1) and the peripheral connection contact plug 191_C(2) may be spaced apart from each other.

Referring to FIGS. 1C and 1D, the word line connection contact plug 191_C(1) may be provided to penetrate a portion of the filling insulating layer 181 and a portion of the word line capping pattern 154 and may be connected to the first conductive pattern 152. The second conductive pattern PN may be spaced apart from the word line connection contact plug 191_C(1) in the first direction D1.

In the embodiment of FIG. 1C, the word line connection contact plug 191_C(1) may be provided to penetrate a portion of the second device isolation structure 20 and a portion of the word line capping pattern 154 and may be connected to an end portion of the first conductive pattern 152.

In the embodiment of FIG. 1D, the word line connection contact plug 191_C(1) may be provided to penetrate a portion of the word line capping pattern 154, may be connected to an end portion of the first conductive pattern 152, and may be spaced apart from the second device isolation structure 20.

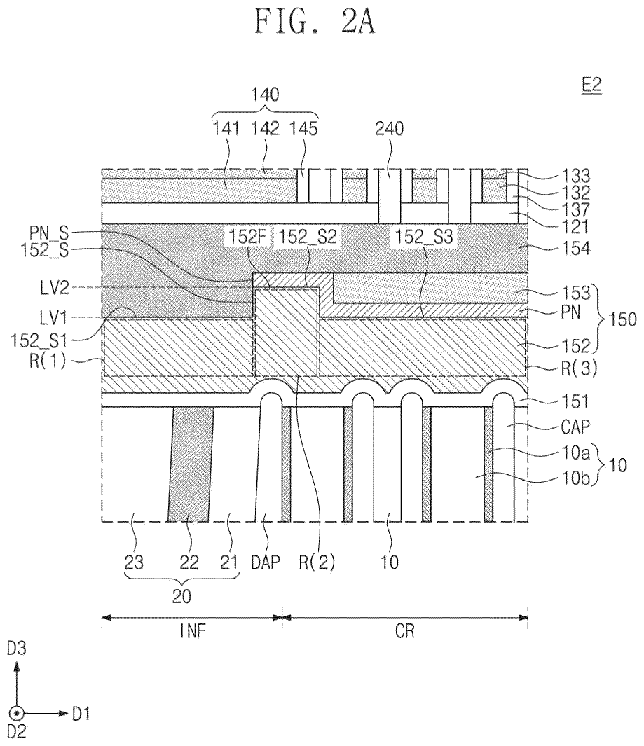

FIGS. 2A and 2B are enlarged sectional views illustrating some embodiments, specifically, corresponding to a portion ‘E2’ of FIGS. 1C and 1D.

In the embodiments of FIGS. 1C, 1D, 2A, and 2B, the first conductive pattern 152 may include a first portion R(1) on the second device isolation structure 20, a second portion R(2) on the second active region DAP, and a third portion R(3) on the first active region CAP. A side surface 152_S of the first conductive pattern 152 may be spaced apart from the word line connection contact plug 191_C(1) in the first direction D1.

The second portion R(2) of the first conductive pattern 152 may include an upper protruding portion 152F. The second conductive pattern PN may cover the upper protruding portion 152F of the second portion R(2) and the third portion R(3). The second conductive pattern PN may not cover the first portion R(1). A first top surface 152_S1 of the first conductive pattern 152, which is not covered with the second conductive pattern PN, may be covered with the word line capping pattern 154. Thus, any void may be absent on the dummy region INF and between the first conductive pattern 152 and the word line capping pattern 154. This configuration may make it possible to improve the reliability of the semiconductor memory device. The third conductive pattern 153 may cover the second conductive pattern PN on the third portion R(3). The third conductive pattern 153 may not cover the second conductive pattern PN on the second portion R(2).

The side surface 152_S of the upper protruding portion 152F may be aligned to a side surface PN_S of the second conductive pattern PN covering the upper protruding portion 152F. In other words, in an embodiment, the side surface 152_S of the upper protruding portion 152F may be coplanar with a side surface PN_S of the second conductive pattern PN covering the upper protruding portion 152F. The side surface 152_S of the upper protruding portion 152F and the side surface PN_S of the second conductive pattern PN may be spaced apart from the word line connection contact plug 191_C(1) in the first direction D1.

A top surface of the third conductive pattern 153 on the first active region CAP and a top surface of the second conductive pattern PN on the second active region DAP may be placed at substantially the same level. In other words, in an embodiment, the top surface of the third conductive pattern 153 on the first active region CAP may be coplanar with the top surface of the second conductive pattern PN on the second active region DAP.

In the embodiment of FIG. 2A, a first level LV1 of the first top surface 152_S1 of the first portion R(1) may be lower than a second level LV2 of a second top surface 152_S2 of the second portion R(2). The first level LV1 of the first top surface 152_S1 of the first portion R(1) may be equal to the first level LV1 of a third top surface 152_S3 of the third portion R(3).

In the embodiment of FIG. 2B, a third level LV3 of the first top surface 152_S1 of the first portion R(1) may be lower than the first level LV1 of the third top surface 152_S3 of the third portion R(3).

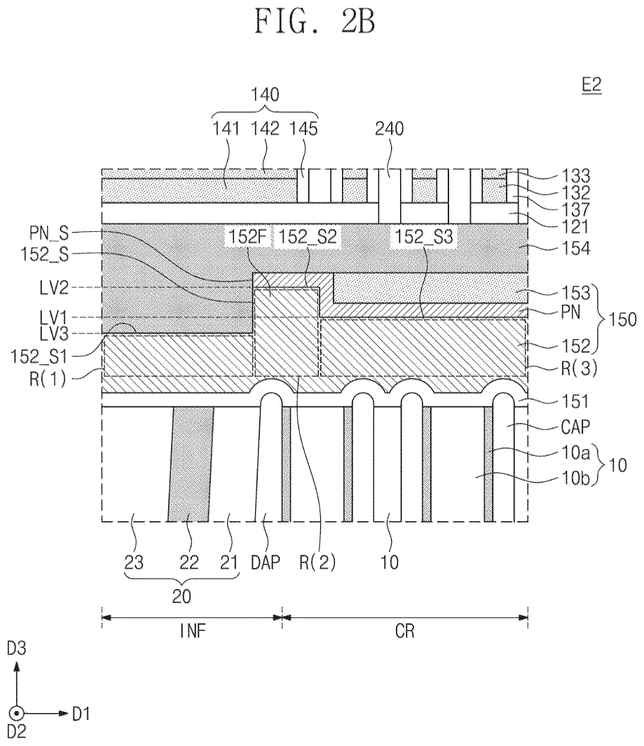

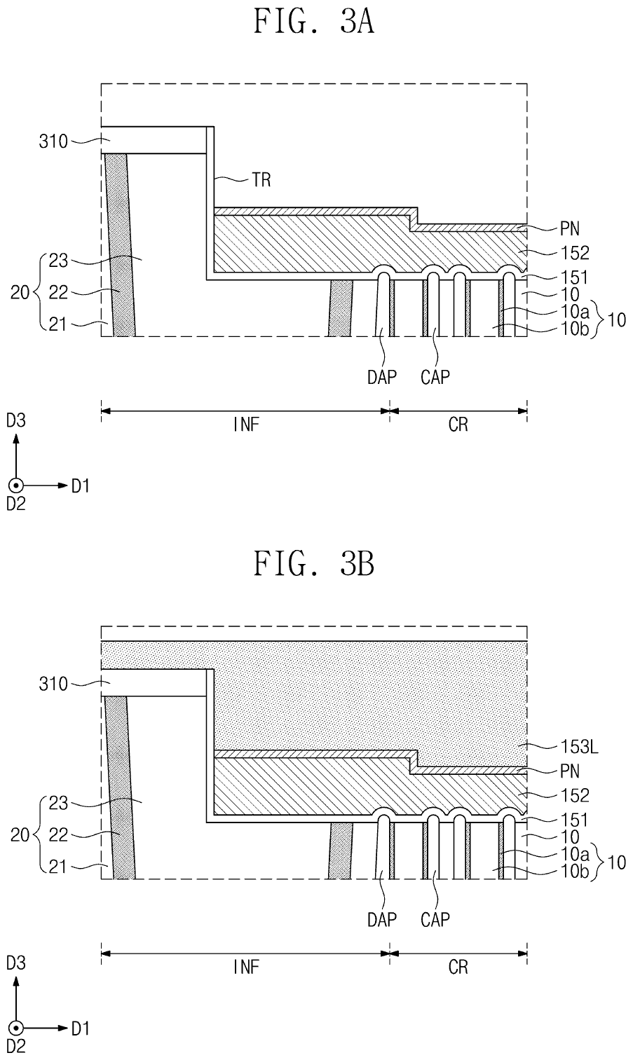

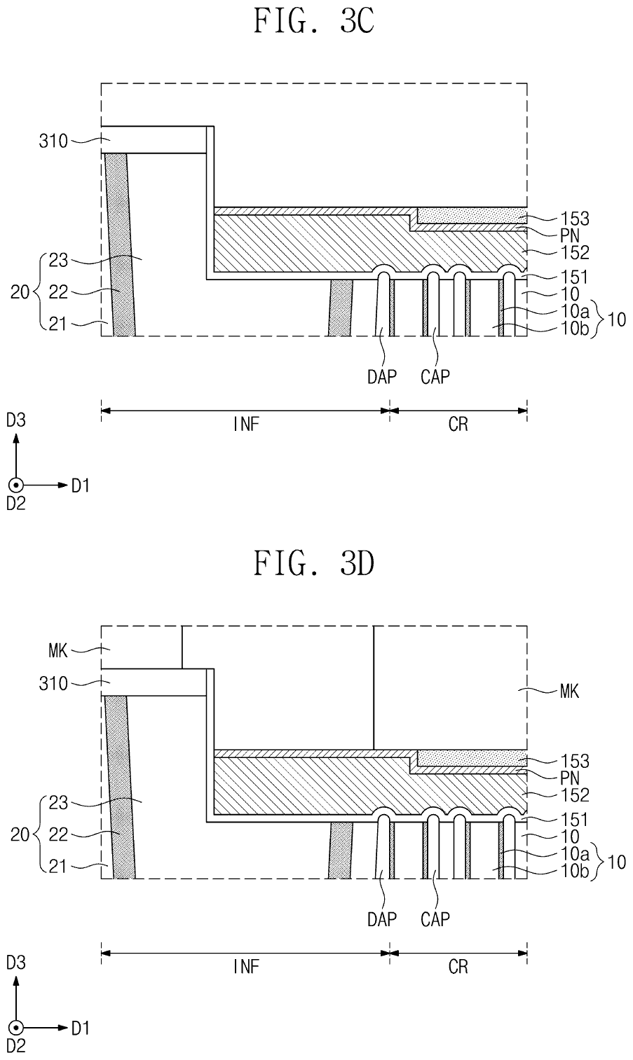

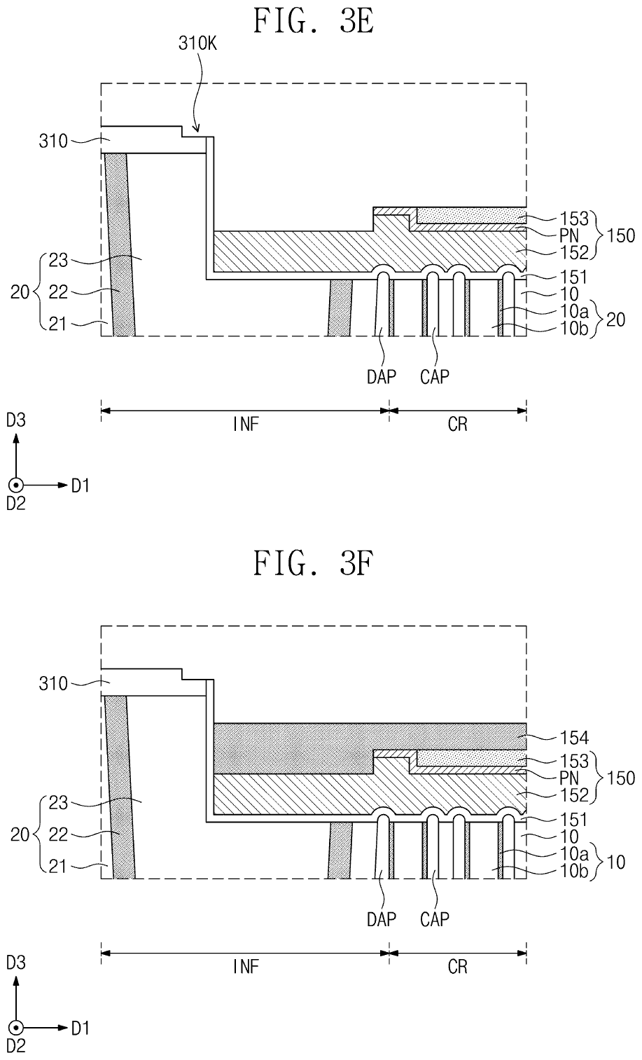

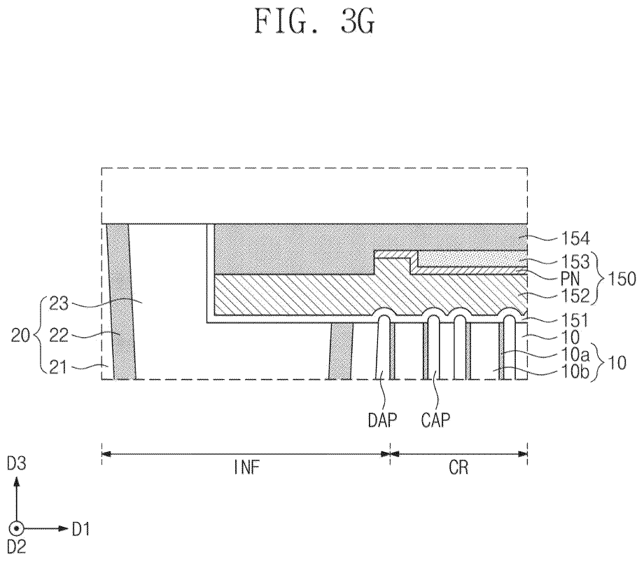

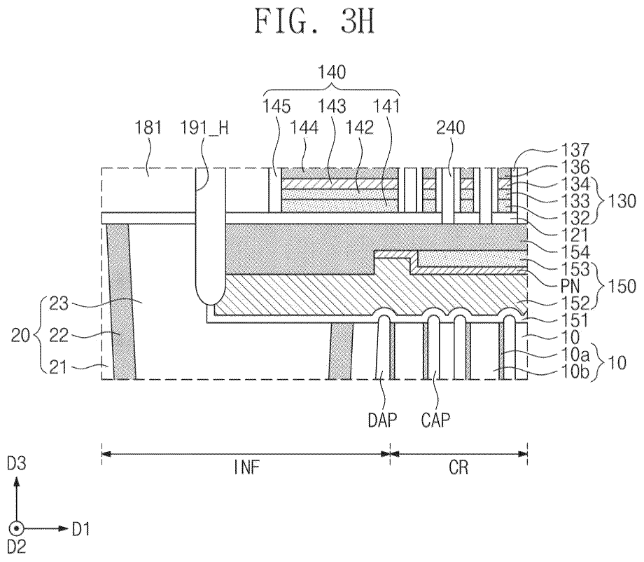

FIGS. 3A to 3H are enlarged views sequentially illustrating a process of fabricating a semiconductor memory device having the section of FIG. 1C.

Referring to FIG. 3A, the substrate 100 including the cell region CR and the dummy region INF may be provided. The first and second device isolation structures 10 and 20 may be formed in the substrate 100 to delimit the first active region CAP in the cell region CR and to delimit the second active region DAP in the dummy region INF.

A groove TR may be formed in the substrate 100 to penetrate the first and second active regions CAP and DAP. In more detail, a cover insulating layer 310 may be formed on the substrate 100 to define the shape of a word line. The cover insulating layer 310, the first active region CAP, the second active region DAP, the first device isolation structure 10, and a portion of the second device isolation structure 20 may be etched to form the groove TR in an upper portion of the substrate 100. Thereafter, the gate dielectric layer 151 may be formed in the groove TR. The cover insulating layer 310 may include an insulating material (e.g., an oxide material). The gate dielectric layer 151 may include at least one of thermal oxide, silicon nitride, silicon oxynitride, or high-k dielectric materials.

A first preliminary conductive layer (not shown) may be formed to fill the groove TR. The first preliminary conductive layer (not shown) may be extended to cover the cover insulating layer 310. The first preliminary conductive layer (not shown) may include a conductive material. For example, the first preliminary conductive layer (not shown) may be formed of or include titanium nitride. In an embodiment, the formation of the first preliminary conductive layer (not shown) may include depositing a conductive material and performing a chemical mechanical polishing process. The first conductive pattern 152 may be formed by etching the first preliminary conductive layer (not shown) using a photoresist pattern as an etch mask. The first conductive pattern 152 may be formed by etching the first preliminary conductive layer (not shown) to have a top surface lower than the cover insulating layer 310. The top surface of the first conductive pattern 152 may have a stepwise shape between the cell region CR and the dummy region INF.

For example, the first preliminary conductive layer (not shown) may be etched by an etch-back process. In an embodiment, a strip process and a thermal treatment process may be performed after the etching of the first preliminary conductive layer.

A process, which is the same or similar to that for the first conductive pattern 152, may be performed to form a second preliminary conductive layer (not shown) and to form the second conductive pattern PN covering the first conductive pattern 152. The second preliminary conductive layer (not shown) may include a conductive material. The second preliminary conductive layer (not shown) may be formed of or include, for example, molybdenum (Mo). The top surface of the second conductive pattern PN may have a stepwise shape between the cell region CR and the dummy region INF.

Referring to FIG. 3B, a third preliminary conductive layer 153L may be formed to cover the second conductive pattern PN and the cover insulating layer 310. The third preliminary conductive layer 153L may include a conductive material. The third preliminary conductive layer 153L may be formed of or include, for example, poly silicon.

Referring to FIG. 3C, the third preliminary conductive layer 153L may be etched through the same or a similar process as that used to form the first conductive pattern 152, and as a result, the third conductive pattern 153 may be formed on the first active region CAP to cover the second conductive pattern PN. A top surface of the second conductive pattern PN on the second active region DAP and a top surface of the third conductive pattern 153 on the first active region CAP may be located at the same level.

Referring to FIG. 3D, a mask pattern MK may be formed to cover the cover insulating layer 310 and the first and second active regions CAP and DAP and to expose the second conductive pattern PN on the dummy region INF. The mask pattern MK may be formed to expose an end portion of the cover insulating layer 310. The mask pattern MK may be a photoresist pattern.

Referring to FIGS. 3D and 3E, the first and second conductive patterns 152 and PN on the dummy region INF may be etched using the mask pattern MK through the afore-described process of forming the first conductive pattern 152. The cover insulating layer 310 may have an etch selectivity different from the first and second conductive patterns 152 and PN, and thus, an end portion of the cover insulating layer 310 may be partially etched. An end portion 310K of the cover insulating layer 310 etched may have a stepwise shape. The end portion 310K may be used as a guiding element in a subsequent etching process to form a word line contact hole 191_H. The etched first conductive pattern 152 on the dummy region INF and the second conductive pattern PN adjacent to the dummy region INF may be formed to have top surfaces that are formed to have a stepwise shape. As a result of the afore-described process, the word line 150 may be formed.

The first conductive pattern 152, the second conductive pattern PN, and the cover insulating layer 310 may be etched by an etch-back process. The mask pattern MK may be removed, after the etching of the first conductive pattern 152, the second conductive pattern PN, and the cover insulating layer 310. For example, the mask pattern MK may be removed by an ashing process and/or a strip process.

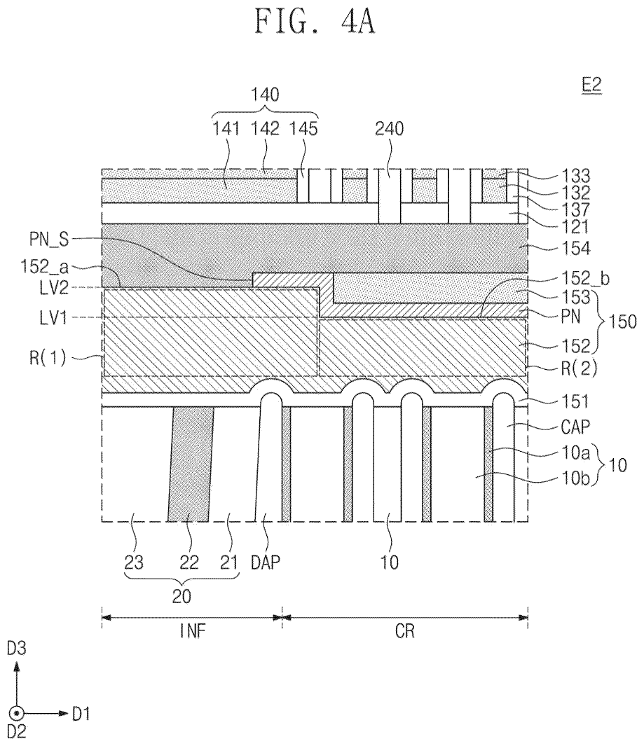

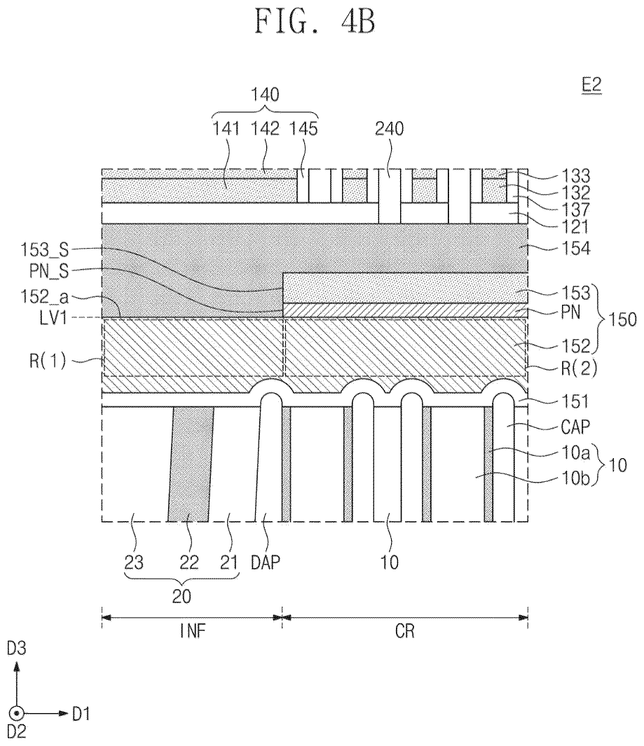

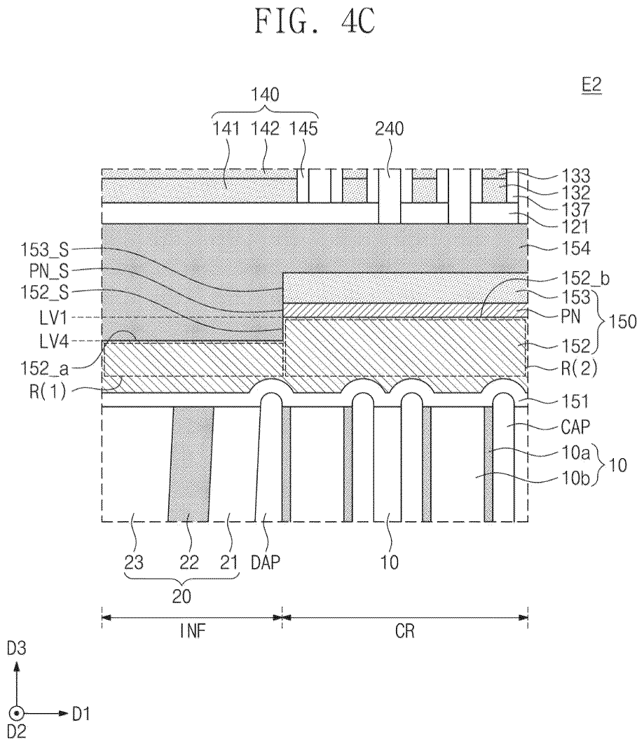

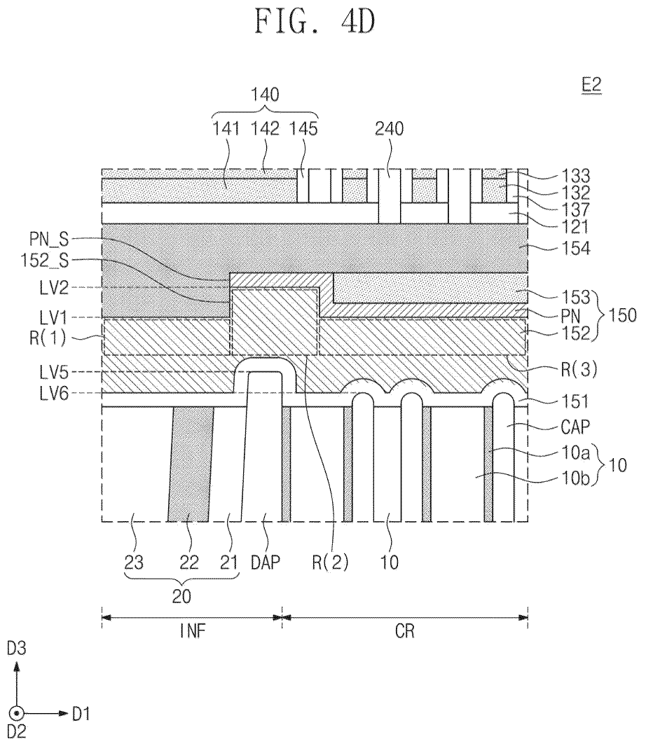

However, unlike the illustrated structure, the first conductive pattern 152 on the dummy region INF may not be etched, and the second conductive pattern PN on the dummy region INF may be selectively etched. In this case, the semiconductor memory device may have the section to be described with reference to FIG. 4A.

Referring to FIG. 3F, a preliminary insulating layer (not shown) may be formed to cover the first and third conductive patterns 152 and 153 and the cover insulating layer 310. An etch-back process may be performed on the preliminary insulating layer to form the word line capping pattern 154 covering the word line 150. The preliminary insulating layer may include an insulating material. For example, the preliminary insulating layer may include a nitride material.

Referring to FIG. 3G, the cover insulating layer 310 may be removed. For example, in an embodiment, an etch-back process may be performed to etch a portion of the second device isolation structure 20, a portion of the gate dielectric layer 151, and a portion of the word line capping pattern 154 and the cover insulating layer 310. In some embodiments, the cover insulating layer 310 may be removed by a strip process. The second device isolation structure 20, the gate dielectric layer 151, and the word line capping pattern 154 may have top surfaces that are exposed to the outside at the same level.

Referring to FIGS. 1C and 3H, the interlayer insulating pattern 121, the bit lines 130, the dummy gate structure 140, the peripheral gate structure 160, the filling insulating layer 181, the insulating fence 240, and the landing pad isolation pattern 250 may be formed.

The word line contact hole 191_H may be formed by partially etching the second device isolation structure 20 (i.e., the fifth sub-device isolation insulating layer 23), the gate dielectric layer 151, the word line capping pattern 154, the first conductive pattern 152, and the filling insulating layer 181 on the dummy region INF. The word line contact hole 191_H may be spaced apart from the second conductive pattern PN.

Since, on the dummy region INF between the word line contact hole 191_H and the second conductive pattern PN, the first conductive pattern 152 is covered with the word line capping pattern 154, it may be possible to prevent a Galvanic corrosion phenomenon from occurring in the second conductive pattern PN by a cleaning solution used in a step of cleaning the word line contact hole 191_H after the formation of the word line contact hole 191_H. The Galvanic corrosion phenomenon may occur when two different metals with distinct electric potentials are electrically connected in the presence of an electrolyte solution, causing the metal with the lower potential to corrode. Thus, it may be possible to prevent a void from being formed between the first conductive pattern 152 and the word line capping pattern 154. Accordingly, it may be possible to provide a semiconductor memory device with low failure rate and high reliability.

Thereafter, a conductive material may be formed to fill the word line contact hole 191_H, and the conductive structure 191 connected thereto may be formed to fabricate a semiconductor memory device having the section of FIG. 1C.

FIGS. 4A to 4D are enlarged sectional views illustrating some embodiments, specifically, corresponding to the portion ‘E2’ of FIGS. 1C and 1D.

Referring to FIG. 4A, the first conductive pattern 152 in the embodiment illustrated in FIG. 4A may include the first portion R(1), which is provided on the second device isolation structure 20 and the second active region DAP, and the second portion R(2), which is provided on the first active region CAP. A first level LV1 of a top surface 152_b of the second portion R(2) may be lower than a second level LV2 of a top surface 152_a of the first portion R(1).

The third conductive pattern 153 may be disposed on the second portion R(2). The second conductive pattern PN may be interposed between the first conductive pattern 152 and the third conductive pattern 153. The second conductive pattern PN may extend to cover an end portion of the first portion R(1) of the first conductive pattern 152. The side surface PN_S of the extended second conductive pattern PN may be placed on the second device isolation structure 20 to be adjacent to an edge of the second device isolation structure 20. Except for the afore-described differences, the semiconductor memory device according to the embodiment illustrated in FIG. 4A may have substantially the same features as that described with reference to FIGS. 1A to 1G and thus repeated description thereof is omitted for conciseness.

Referring to FIG. 4B, the first conductive pattern 152 may include the first portion R(1) on the dummy region INF and the second portion R(2) on the cell region CR. The top surface 152_a of the first and second portions R(1) and R(2) may be flat and may not have any stepwise portion. The second and third conductive patterns PN and 153 may be sequentially disposed on the second portion R(2). The side surface PN_S of the second conductive pattern PN and a side surface 153_S of the third conductive pattern 153 may be aligned to each other and may be adjacent to the dummy region INF. In other words, the side surface PN_S of the second conductive pattern PN may be coplanar with the side surface 153_S of the third conductive pattern 153 and may be adjacent to the dummy region INF. Except for the afore-described differences, the semiconductor memory device according to the embodiment illustrated in FIG. 4B may have substantially the same features as that described with reference to FIGS. 1A to 1G and thus repeated description thereof is omitted for conciseness.

Referring to FIG. 4C, a fourth level LV4 of the top surface 152_a of the first portion R(1) may be lower than a first level LV1 of the top surface 152_b of the second portion R(2). The side surface 152_S of the second portion R(2), the side surface PN_S of the conductive pattern PN, and the side surface 153_S of the third conductive pattern 153 may be aligned to each other. In other words, the side surface 152_S of the second portion R(2), the side surface PN_S of the conductive pattern PN, and the side surface 153_S of the third conductive pattern 153 may be coplanar. Except for the afore-described differences, the semiconductor memory device according to the embodiment illustrated in FIG. 4C may have substantially the same features as that described with reference to FIGS. 1A to 1G and FIG. 4B and thus repeated description thereof is omitted for conciseness.

Referring to FIG. 4D, a fifth level LV5 of a top surface of the second active region DAP may be higher than a sixth level LV6 of a top surface of the first active region CAP. Except for the afore-described differences, the semiconductor memory device according to the embodiment illustrated in FIG. 4D may have substantially the same features as that described with reference to FIGS. 1A to 2B and thus repeated description thereof is omitted for conciseness.

In a semiconductor memory device according to various embodiments and a method of fabricating the same, a void may not be formed between a first conductive pattern, which is connected to a word line connection contact plug, and a word line capping pattern, which is provided to cover the first conductive pattern, and this may make it possible to reduce a failure rate. In addition, a second conductive pattern may be disposed on the first conductive pattern to be spaced apart from the word line connection contact plug, and the second conductive pattern may be formed of or include molybdenum (Mo). In this case, it may be possible to reduce the electric resistance of the semiconductor memory device. Accordingly, the operation speed of the semiconductor memory device may be increased, and the reliability of the semiconductor memory device may be improved.

While various example embodiments have been particularly shown and described with reference to the drawings, it will be understood by one of ordinary skill in the art that variations in form and detail may be made therein without departing from the spirit and scope of the attached claims.

1. A semiconductor memory device comprising:
a substrate including a first active region and a second active region;
a first device isolation structure and a second device isolation structure disposed in the substrate, the first device isolation structure delimiting the first active region, the second active region being between the first device isolation structure and the second device isolation structure;
a word line in the substrate, crossing the first active region and the second active region, and overlapping the second device isolation structure; and
a word line connection contact plug spaced apart from the second active region and connected to an end portion of the word line,
wherein the word line comprises:
a first conductive pattern;
a second conductive pattern on the first conductive pattern and covering the first active region and the second active region; and
a third conductive pattern on the second conductive pattern and covering the first active region,
wherein the second conductive pattern is spaced apart from the word line connection contact plug.

2. The semiconductor memory device of claim 1, further comprising a word line capping pattern in the substrate and covering the word line,
wherein a bottom surface of the word line capping pattern has a stepwise shape.

3. The semiconductor memory device of claim 2, wherein the word line connection contact plug is provided to penetrate a portion of the word line capping pattern.

4. The semiconductor memory device of claim 1, further comprising a bit line that crosses the word line and is connected to the first active region.

5. The semiconductor memory device of claim 1, wherein, on the second active region, the first conductive pattern comprises an upper protruding portion,
the second conductive pattern covers the upper protruding portion, and
a side surface of the upper protruding portion is coplanar with a side surface of the second conductive pattern.

6. The semiconductor memory device of claim 1, wherein a top surface of the third conductive pattern on the first active region is located on a same level with a top surface of the second conductive pattern on the second active region.

7. The semiconductor memory device of claim 1, wherein a level of a first top surface of the first conductive pattern on the second device isolation structure is equal to or lower than a level of a second top surface of the first conductive pattern on the first active region.

8. The semiconductor memory device of claim 1, wherein the first conductive pattern and the second conductive pattern comprise different materials from each other.

9. The semiconductor memory device of claim 8, wherein the second conductive pattern comprises molybdenum.

10. The semiconductor memory device of claim 1, wherein a level of a top surface of the second active region is higher than a level of a top surface of the first active region.

11. A semiconductor memory device comprising:
a substrate including a peripheral region, a dummy region, and a cell region sequentially arranged in a first direction;
a first device isolation structure disposed in the cell region to delimit first active regions;
a second device isolation structure disposed in the dummy region and the peripheral region to delimit second active regions;
word lines disposed in the dummy region and the cell region to cross the first active regions and the second active regions in the first direction; and
bit lines disposed on the cell region, the bit lines being connected to the first active regions and extending in a second direction orthogonal to the first direction,
wherein each of the word lines comprises:
a first conductive pattern comprising a first portion on the second device isolation structure and the second active regions, and a second portion on the first active regions;
a second conductive pattern on the second portion of the first conductive pattern; and
a third conductive pattern interposed between the first conductive pattern and the second conductive pattern,
wherein the third conductive pattern extends to cover an end portion of the first portion of the first conductive pattern, and
wherein a side surface of the third conductive pattern that is extended is placed adjacent to an edge of the second device isolation structure.

12. The semiconductor memory device of claim 11, further comprising a word line capping pattern on each of the word lines,
wherein, for each of the word lines, a top surface of the first conductive pattern, which is not covered with the third conductive pattern in the dummy region, is covered with the word line capping pattern.

13. The semiconductor memory device of claim 12, further comprising a word line connection contact plug, which is provided to penetrate a portion of the second device isolation structure and a portion of the word line capping pattern and is connected to an end portion of the first conductive pattern,
wherein the side surface of the third conductive pattern is spaced apart from the word line connection contact plug in the first direction.

14. The semiconductor memory device of claim 11, wherein a level of the top surface of the first conductive pattern is higher in the dummy region than in the cell region.

15. The semiconductor memory device of claim 11, wherein the first conductive pattern and the third conductive pattern comprise different materials from each other, and
the third conductive pattern comprises molybdenum.

16. A semiconductor memory device comprising:
a substrate including a peripheral region, a dummy region, and a cell region sequentially arranged in a first direction;
a first active region and a second active region disposed in the cell region and the dummy region, respectively; and
a word line in the substrate, the word line crossing the first active region and the second active region,
wherein the word line comprises:
a first conductive pattern disposed in the cell region and the dummy region; and
a second conductive pattern and a third conductive pattern sequentially stacked on the first conductive pattern, in the cell region,
wherein a first side surface of the second conductive pattern is coplanar with a second side surface of the third conductive pattern, and
the first side surface and the second side surface are adjacent to the dummy region.

17. The semiconductor memory device of claim 16, further comprising:
a device isolation structure disposed in the substrate to delimit the second active region;
a word line capping pattern on the word line; and
a word line connection contact plug that penetrates a portion of the device isolation structure and a portion of the word line capping pattern and is connected to an end portion of the first conductive pattern.

18. The semiconductor memory device of claim 17, wherein the first side surface of the second conductive pattern and the second side surface of the third conductive pattern are spaced apart from the word line connection contact plug in the first direction.

19. The semiconductor memory device of claim 16, wherein a level of a top surface of the first conductive pattern is lower in the dummy region than in the cell region.

20. The semiconductor memory device of claim 16, further comprising:
a storage node contact on the first active region;
a landing pad on the storage node contact; and
a data storage pattern electrically connected to the landing pad.

21-25. (canceled)
